(19) United States
(12) Patent Application Publication
(10) Pub. No.: US 2007/0240859 A1
(43) Pub. Date: Oct. 18, 2007

(54) Capillary structure of heat pipe

(75) Inventors: Tony Wang, Taipei (TW); Meng-Cheng Huang, Taipei (TW); Ming Ta Tsai, Taipei (TW)

Correspondence Address: HDSL, 4331 STEVENS BATTLE LANE, FAIRFAX, VA, 22033, US

(73) Assignee: Chaun-Choung Technology Corp.

(21) Appl. No.: 11/404,793

(22) Filed: Apr. 17, 2006

(51) Int. Cl. H05K 7/20

(52) U.S. Cl. 165/104.26; 165/104.33; 361/700

(57) ABSTRACT

A capillary structure of a heat pipe includes a hollow pipe body and a capillary structure adhered to the inner wall of the pipe body. The main part of the pipe body is provided with at least one heated section. The capillary structure within the heated section is constituted by sintered powder, and the capillary structure within the remaining portion of the main part of the pipe body is constituted by woven web or groove. By using two different kinds of capillary structures to form the capillary structure of the inner wall of the heat pipe, the heat pipe can withstand a heat source of higher temperature, and can also be suitable for a curved pipe.

### BACKGROUND OF THE INVENTION

1. Field of the Invention

The present invention relates to an improved capillary structure of a heat pipe, and in particular to an improved capillary structure of a heat pipe constituted by sintered powders and woven webs or grooves.

2. Description of Prior Art

Heat pipe is a heat-conducting element having high capacity and speed of conducting heat, which is capable of conducting a great amount of heat without consuming too much power. Therefore, the heat pipe is widely used in the field of heat dissipation. The inner wall face of the pipe body of the existing heat pipe is provided with a capillary structure constituted by woven webs or sintered powders functioning as a capillary. With the capillary action of the capillary structure, the delivery of the working fluid within the heat pipe can be achieved.

However, the capillary structure constituted by the woven webs or sintered powder has some advantages and disadvantages as follows.

With regard to the capillary structure constituted by the sintered powder, the structure thereof can withstand greater amount of heat and provide a better capillary force due to the fineness of the powder. However, after being manufactured completely, the sintered powder is adhered to the wall of the heat pipe and formed into a solid. As a result, the heat pipe cannot be formed into a L-shaped pipe or U-shaped pipe by bending. Otherwise, the sintered powder will fragment to peel off the inner wall of the heat pipe. As a result, the capillary structure becomes discontinuous and thus cannot smoothly deliver the working fluid.

On the other hand, with regard to the capillary structure constituted by woven webs, it is more suitable to serve as the capillary structure for a curved heat pipe due to its better flexibility. However, since the woven webs are made by weaving a plurality of metallic wires to form webs, the structure thereof cannot withstand high amount of heat to the same extent as that of the sintered powder. Especially in the heated end of the heat pipe, the woven webs may peel off the inner wall of the heat pipe due to the excessive heat.

Therefore, in view of the above the drawbacks, the inventor proposes the present invention to overcome the above problems based on his expert experiences and deliberate researches.

### SUMMARY OF THE INVENTION

The present invention is to provide an improved capillary structure of a heat pipe characterized in that at the heated end of the heat pipe, sintered powder is used to be the capillary structure of the inner wall of the heat pipe, and the capillary structure of the remaining portion of the main part within the heat pipe is constituted by other kind of capillary structure, such as woven webs or grooves. By using two different kinds of capillary structures to form the capillary structure of the inner wall of the heat pipe, the heat pipe can withstand a heat source of higher temperature, and can also be suitable for a curved pipe.

The present invention provides an improved capillary structure of the heat pipe, which comprises a hollow pipe body, a first kind of capillary structure and a second kind of capillary structure provided on the inner wall of the pipe body. The main part of the pipe body is provided with at least one heated section. The inner wall face of the heated section is provided with the first kind of capillary structure, and the inner wall face of the remaining portion of the main part of the pipe body is provided with the second kind of capillary structure. The first kind of capillary structure is constituted by sintered powder. With the above constitution, the objects of the present invention can be achieved.

### BRIEF DESCRIPTION OF THE DRAWINGS

FIG. 1 is a cross-sectional view of the present invention;

FIG. 2 is a partially enlarged view showing the details in FIG. 1;

FIG. 3 is a cross-sectional view of a first embodiment of the present invention;

FIG. 4 is a cross-sectional view of a second embodiment of the present invention; and

FIG. 5 is a cross-sectional view of a third embodiment of the present invention.

### DETAILED DESCRIPTION OF THE INVENTION

In order to make the Examiner better understand the characteristics and the technical contents of the present invention, a detailed description relating to the present invention will be made with reference to the accompanying drawings. However, it should be understood that the drawings are illustrative but not used to limit the scope of the present invention.

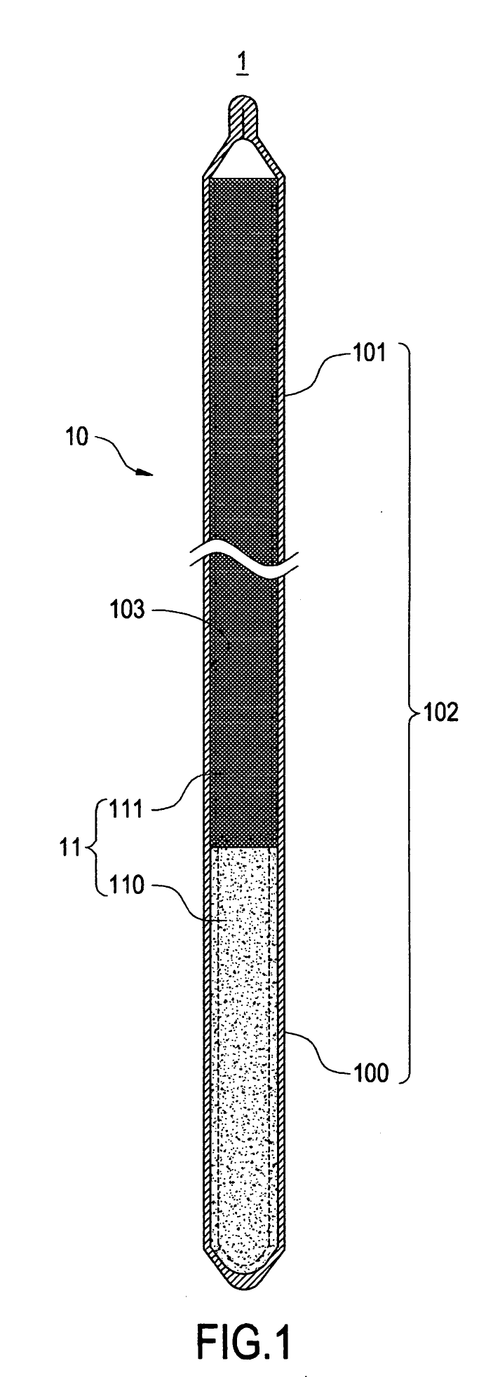

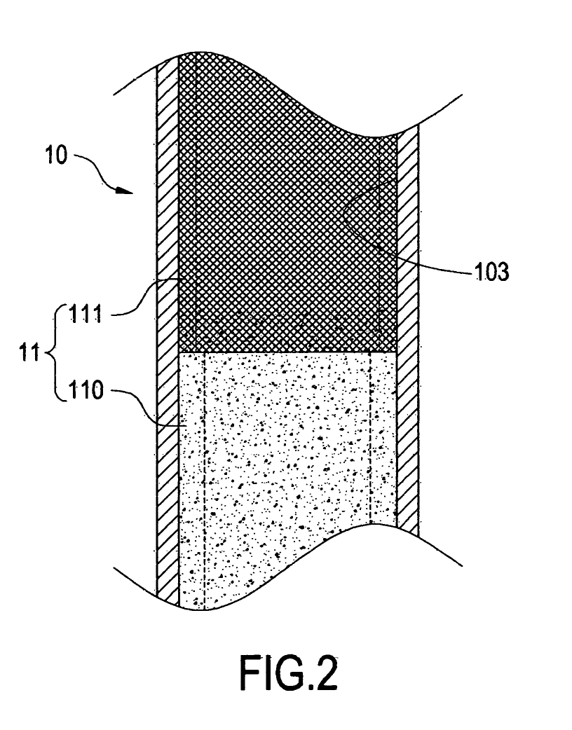

FIG. 1 is a cross-sectional view of the present invention, and FIG. 2 is a partially enlarged view showing the details in FIG. 1. The present invention provides an improved capillary structure of the heat pipe. The interior of the heat pipe 1 is vacuum. The heat pipe is a sealed pipe having a proper length and enclosed a proper amount of working fluid (not shown) therein. The heat pipe 1 comprises a hollow pipe body 10 and the capillary structure 11 provided on the inner wall face of the pipe body 10. The pipe body 10 is a hollow pipe made of cupper. The length of the heat pipe can be properly selected depending on the actual requirements. Usually, the bottom end of the heat pipe is firstly sealed and then subjected to heat treatment. Thereafter, the capillary structure and a working fluid are disposed therein, and a degassing process is performed. After this, the top end of the heat pipe can be sealed, thereby to finish the heat pipe 1. However, the manufacturing process is conventional and not within the scope of the present invention. Therefore, the description thereof is omitted.

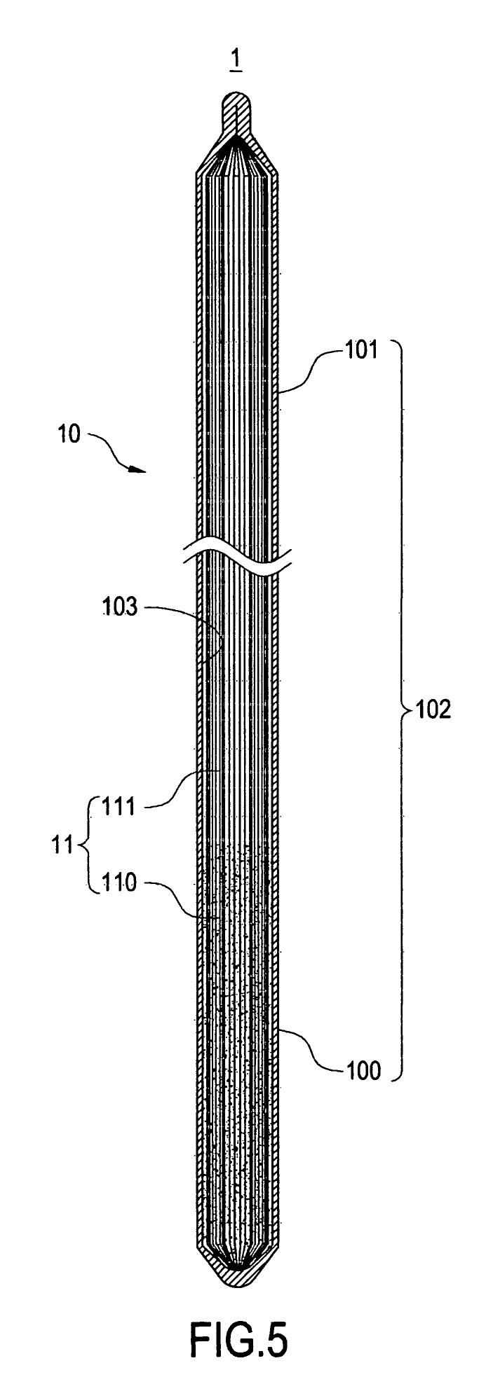

The capillary structure 11 is circumferentially adhered to the inner wall face of the pipe body 10. Specifically, the capillary structure is adhered to the inner wall face 103 of the whole main part 102 of the pipe body 10. When the bottom end of the heat pipe 1 is heated, the working fluid within the heat pipe 1 is heated to change from liquid phase into vapor phase, the heat can be conducted from the bottom end to the top end of the heat pipe 1. After being cooled at the top end, the vapor-phase working fluid returns to liquid phase. At the same time, with the capillary action of the capillary structure 11, the working fluid can be easily flowed back to the bottom end of the heat pipe 1, thereby to continuously perform the circulation of heat exchange. The present invention lies in that the main part 102 of the pipe body 10 is provided with at least one heated section 100. As shown in FIG. 1, the heated section 100 is provided at the bottom end of the heat pipe. At the same time, the capillary structure 11 within the pipe body 10 is constituted by two different kinds of capillary materials. Specifically, the capillary structure adhered to the inner wall face 103 of the heated section 100 is a first kind of capillary structure 110 made of sintered powder. The capillary structure provided on the inner wall face 103 of the remaining portion of the main part 102 of the pipe body 10 is a second kind of capillary structure 111. The second kind of capillary structure can be woven webs made by weaving wires (as shown in FIG. 1). After the woven webs are curled, they are adhered to the inner wall face 103 of the pipe body 10. Alternatively, by drawing the pipe, a capillary structure having grooves can be formed on the inner wall face 103 of the pipe body 10 (as shown in FIG. 5). The second kind of capillary structure 111 is provided at the condensed section 101 on the top end of the heat pipe 1 and the remaining portion of the main part 102.

As shown in FIG. 2, in order to avoid the discontinuity in capillary delivery caused by the disconnection between the first and second kinds of capillary structures, the connecting points between these two kinds of capillary materials are preferably overlapped or tightly butted to assure the path for capillary delivery is continuous without any interruption.

Therefore, with the above constitution, the improved capillary structure of the heat pipe can be obtained.

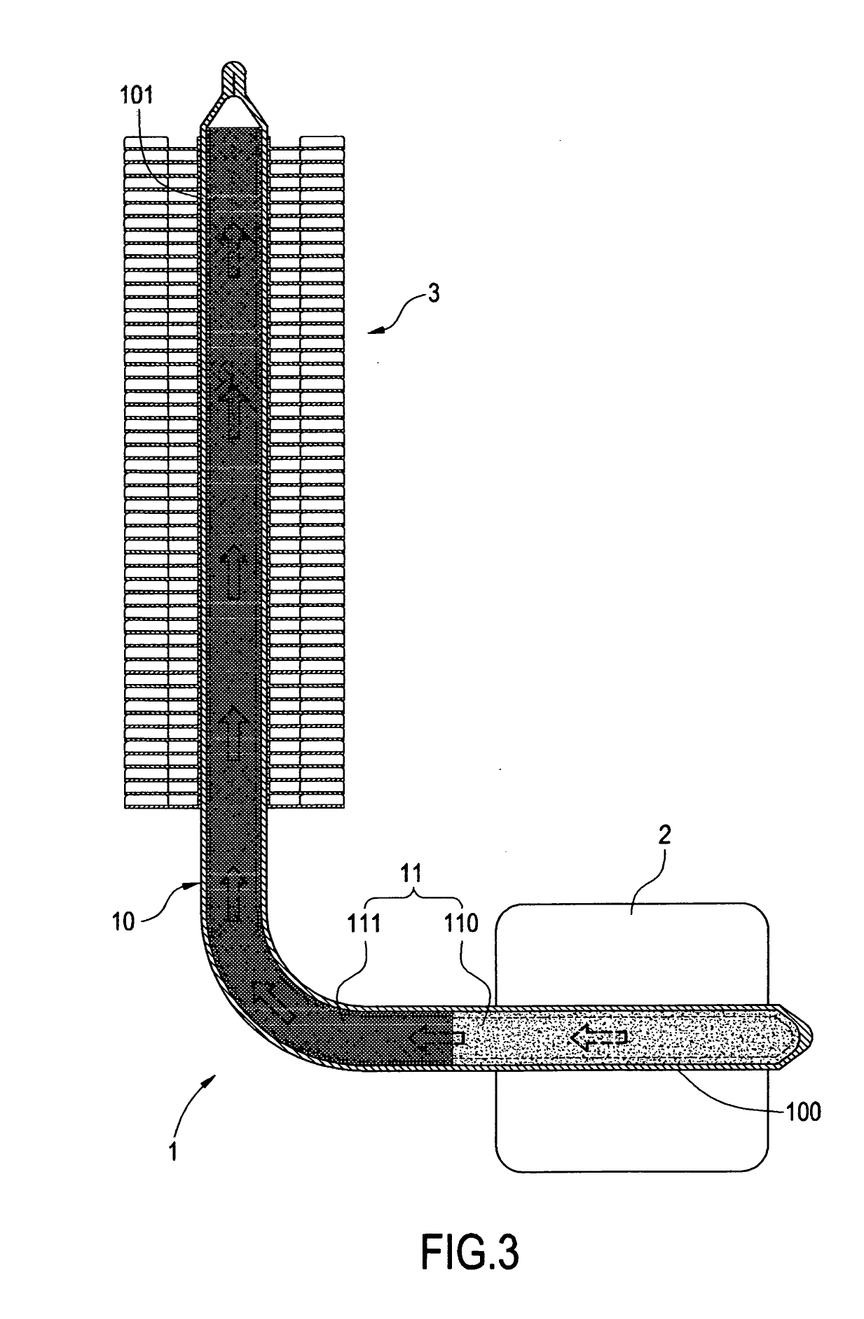

As shown in FIG. 3, it is a schematic view showing the state in which the heat pipe 1 of the present invention is applied to a L-shaped pipe. The heated section 100 is formed at one end of the heat pipe 1 while the other end is formed with the condensed section 101. The heated section 100 is brought into contact with a heat source 2. The condensed section 101 is connected to a plurality of heat-dissipating fins 3. The second kind of capillary structure 111 provided within the portion of the heat pipe 1 to be bent is constituted by woven webs or grooves. Therefore, the heat pipe 1 can be bent without breaking the capillary structure.

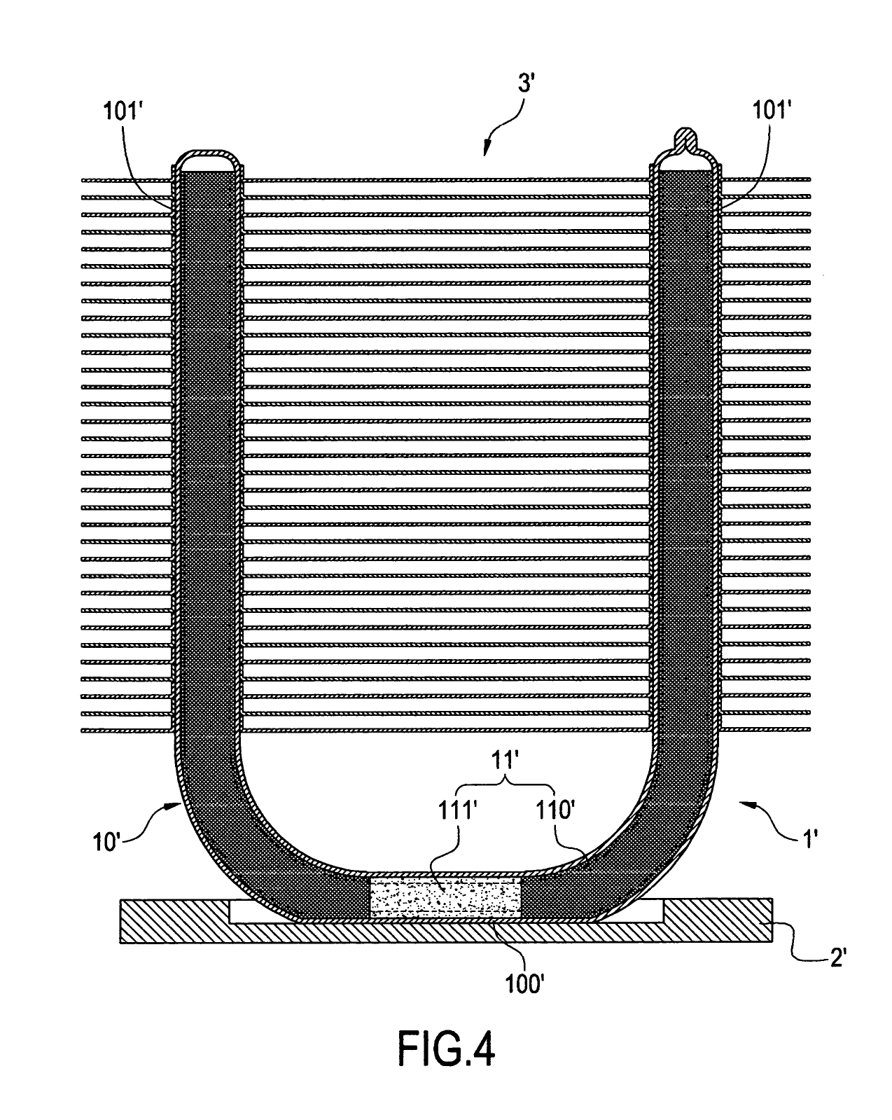

As shown in FIG. 4, it is a schematic view showing the state in which the heat pipe 1′ of the present invention is applied to a U-shaped pipe. Since the heated section 100′ of the U-shaped heat pipe 1′ is provided at the bottom end thereof. Therefore, in the present embodiment, the heated section 100′ is formed in the middle of the pipe body 10′. Also, each of both ends of the pipe body 10′ is provided with the condensed section 101′. The heated section 100′ is also brought into contact with a heat source 2′. Both condensed sections 101′ are connected to a plurality of heat-dissipating fins 3′ in common. In this way, the capillary structure 11′ having the first kind of capillary structure 110′ made of sintered powder and the second kind of capillary structure 111′ made of woven webs or grooves can be achieved. With such capillary structure 11′, the heated section 100′ of the heat pipe 1′ can withstand a higher temperature and the remaining portion of the pipe body are suitable for bending.

According to the above, the present invent indeed achieves the desired effects and overcomes the drawbacks of prior art by employing the above structures. Therefore, the present invention involves the novelty and inventive steps, and conforms to the requirements for a utility model patent.

Although the present invention has been described with reference to the foregoing preferred embodiments, it will be understood that the invention is not limited to the details thereof. Various equivalent variations and modifications can still be occurred to those skilled in this art in view of the teachings of the present invention. Thus, all such variations and equivalent modifications are also embraced within the scope of the invention as defined in the appended claims.

What is claimed is:

1. A capillary structure of a heat pipe, comprising a hollow pipe body and a first kind of capillary structure and a second kind of capillary structure provided on the inner wall face of the pipe body, wherein
the main part of the pipe body is provided with at least one heated section, the inner wall face of the heated section is provided with the first kind of capillary structure, the inner wall face of the remaining portion of the main part of the pipe body is provided with the second kind of capillary structure, and the first kind of capillary structure is constituted by sintered powder.

2. The capillary structure of a heat pipe according to claim 1, wherein the heated section is provided at one end of the pipe body and the other end of the pipe body is provided with a condensed section.

3. The capillary structure of a heat pipe according to claim 1, wherein the heated section is provided at the middle of the pipe body and each of both ends of the pipe body is provided with a condensed section.

4. The capillary structure of a heat pipe according to claim 1, wherein the connecting points between the first and second kinds of capillary structures are overlapped with each other.

5. The capillary structure of a heat pipe according to claim 1, wherein the connecting points between the first and second kinds of capillary structures are tightly butted.

6. The capillary structure of a heat pip according to claim 1, wherein the second kind of capillary structure is woven webs.

7. The capillary structure of a heat pip according to claim 6, wherein the woven webs are made by weaving metallic wires to form the webs.

8. The capillary structure of a heat pip according to claim 1, wherein the second capillary structure is grooves.
